(19) United States
(12) Patent Application Publication
(10) Pub. No.: US 2015/0260757 A1
(43) Pub. Date: Sep. 17, 2015

(54) PROBE TIP STRUCTURE FOR BONDINGLESS ELECTRONIC LAPPING GUIDE CONNECTIONS

(71) Applicant: Seagate Technology LLC, Cupertino, CA (US)

(72) Inventors: Leping Li, Bloomington, MN (US); Kara L. Maytag, Plymouth, MN (US); Saravuth Keo, Burnsville, MN (US)

(73) Assignee: Seagate Technology LLC, Cupertino, CA (US)

(21) Appl. No.: 14/216,186

(22) Filed: Mar. 17, 2014

(51) Int. Cl. G01R 1/073; G11B 5/31; G01B 7/06

(52) U.S. Cl. CPC G01R 1/07342; G01B 7/06; G11B 5/3169; G11B 5/3166

(57) ABSTRACT

A lapping system including a substrate having an air bearing surface and at least one slider, wherein each slider comprises at least one electronic lapping guide pad, and a probe card comprising at least one extending probe comprising a body member and a distal end, the probe card being movable in a direction of compression between a first position in which the distal end of a first extending probe is spaced from a top surface of one of a first electronic lapping guide pad and a second position in which the distal end of the first extending probe contacts the top surface the first electronic lapping guide pad, wherein the first extending probe is pre-loaded with a predetermined spring force in the direction of compression.

### BACKGROUND

Hard disc drive systems (HDDs) typically include one or more data storage discs. A transducing head carried by a slider is used to read from and write to a data track on a disc. The slider is carried by an arm assembly that includes an actuator arm and a suspension assembly, which can include a separate gimbal structure or can integrally form a gimbal. The transducing heads are typically produced by using thin film deposition techniques. In a typical process, an array of sliders are formed on a common substrate or an AlTiC wafer which is then sliced to produce bars, with a row of sliders in a side-by-side pattern on each bar. The bars are then subjected to a series of processes to form individual sliders, including lapping, cleaning, formation of air-bearing surfaces (ABS), and dicing.

During construction, the air bearing surface is precisely defined so that the sensing element has a precise stripe height, which is the distance between the air bearing surface and the back edge. This is accomplished by lapping the bar sliced off the wafer substrate on which the magnetic read head is constructed. To achieve precise and accurate control of the depth to which the sensing element is lapped, an electronic lapping guide is typically included on the wafer substrate with the sensing element during manufacture. The wafer substrate is then sliced into rows and then lapped prior to formation of the air bearing surface. The electrical resistance of the electronic lapping guide is inversely proportional to the area of the cross-section of an imbedded sensor. Thus, monitoring of the electronic lapping guide resistance during lapping permits very fine adaptive control of the stripe height of the transducer element. For example, the lapping process can be controlled to cease when the electronic lapping guide resistance reaches a predetermined value associated with a desired stripe height of the transducer element.

To achieve the desired precise dimensions prior to the formation of the air bearing surface, the lapping process is typically a multiple step process, which begins with a double-sided lapping (DSL) step, followed by a “rough lapping” step, which is followed by an intermediate “fine lapping” step, and then the process can be completed with a polishing step, often called “kiss lapping” step. The rough lapping step is a relatively aggressive lapping process that requires good adhesion of the slider bar to the lapping carrier in order to avoid the bar being sheared off the carrier during the rough lapping process. Conversely, the kiss lapping step is a final polishing and precision shaping step, which is much less aggressive than the rough lapping step.

In order to start a lapping process, the front surface of the bar is brought into contact with the abrasive surface of the lapping plate. This part of the process can be referred to as the “touchdown”. Because the row bar is typically attached to a carrier via an adhesive (e.g., a hot melt glue), the touchdown process induces compression of the adhesive, which can cause undesirable movement of the electronic lapping guide (ELG) pads. When a probe card with extending probes is used during the lapping process, such a movement of the electronic lapping guides can cause poor contact between the probes and their respective ELG pads. There is a need to provide a probe structure and attachment procedure which will result in desirable, robust contact between the probe tip and the corresponding ELG pad, yet not be cost prohibitive.

### SUMMARY

In one aspect of the present invention, a lapping system is provided that includes a bondingless interconnection structure and associated engagement scheme for more secure contact between a probe tip and an ELG pad to survive the “touchdown” and lapping processes. Such a lapping system includes a substrate comprising a surface to be lapped and at least one slider, wherein each slider includes at least one pair of electronic lapping guide pads. The lapping system also includes a probe card comprising at least one extending probe comprising a body member and a distal end. The probe card is movable in a direction of compression between a first position in which the distal end of a first extending probe is spaced from a top surface of one of a first electronic lapping guide pad and a second position in which the distal end of the first extending probe contacts the top surface of the first electronic lapping guide pad. The first extending probe is pre-loaded with a predetermined spring force in the direction of compression. The interconnect probe assembly can include a plurality of extending probes, wherein each pair of probes can be associated with its corresponding pair of ELG pads on the slider bar. The direction of compression of the probe can be normal to the top contacting surface of at least one electronic lapping guide when the probe card is in the second position.

In the aspect of the invention discussed above, the materials from which the components are made can be particularly designed or selected for certain performance characteristics relative to secure contact between a probe tip and an ELG pad. In particular, the distal end of at least one of the extending probes can include a first material, and the top surface of at least one of the electronic lapping guide pads can include a second material, wherein contact between the distal end of each extending probe and the top surface of the electronic lapping guide pad that it contacts provides a coefficient of friction greater than about 0.8. To that end, the distal end of at least one extending probe can include a gold coating layer, and/or the top surface of at least one of the electronic lapping guide pads can include a gold coating layer.

In another aspect of the present invention, a lapping system is provided that includes a substrate with a front surface where an air bearing surface will be formed later and at least one slider, wherein each slider includes at least one pair of electronic lapping guide pads. The system further includes an interconnect probe assembly having at least one extending probe comprising a body member and a distal end, the probe assembly being movable in a direction of compression between a first position in which the distal end of a first extending probe contacts a top surface of one of the pads of a first electronic lapping guide and a second position in which the distal end of the first extending probe is spaced from the top surface the first electronic lapping guide pad, wherein the distal end of the first extending probe comprises a gold coating layer.

In another aspect of the present invention, a method of manufacturing a magnetic read-write head is provided, the method including the steps of presenting a lapping system to a processing location relative to a lapping device, the lapping system comprising a substrate with a front surface, on which an air-bearing pattern will be formed later, and at least one slider, wherein each slider includes at least one pair of electronic lapping guide pads and a probe assembly comprising at least one pair of extending probes comprising a body member and distal ends. The probe assembly is movable relative to at least one slider in a direction of compression. The method further includes the steps of moving the probe assembly between a first position in which the distal end of a first extending probe is spaced from a top surface of one of a first electronic lapping guide pad to a second position in which the distal end of the first extending probe contacts the top surface the first electronic lapping guide pad, wherein the first extending probe is pre-loaded with a predetermined spring force in the direction of compression (i.e., opposite to the normal direction), and lapping the air bearing surface with the lapping device while measuring the electrical resistance of the first electronic lapping guide with the first extending probe.

These and various other features and advantages will be apparent from a reading of the following detailed description.

### BRIEF DESCRIPTION OF THE DRAWINGS

The present invention will be further explained with reference to the appended Figures, wherein like structure is referred to by like numerals throughout the several views, and wherein:

FIG. 1 is a sectional side view of a magnetic recording disc drive;

FIG. 2 is a top view of the magnetic recording disc drive of FIG. 1;

FIG. 3 is a perspective view of a 6-pair probe card connection;

FIG. 4 is an enlarged perspective view of a portion of FIG. 3, including a pair of probes positioned relative to ELG pads;

FIG. 5 is a graph illustrating six ELG resistance vs. time, including touchdown and lapping process traces for a probe card connection of the type illustrated in FIG. 3;

FIGS. 6a and 6b are side schematic views of an exemplary touchdown between a lapping plate and front lapping surface of a row bar; and

FIG. 7 is an enlarged side view of a portion of the bridge carrier and probe card, showing a specially bent probe tip in contact with an ELG pad.

### DETAILED DESCRIPTION

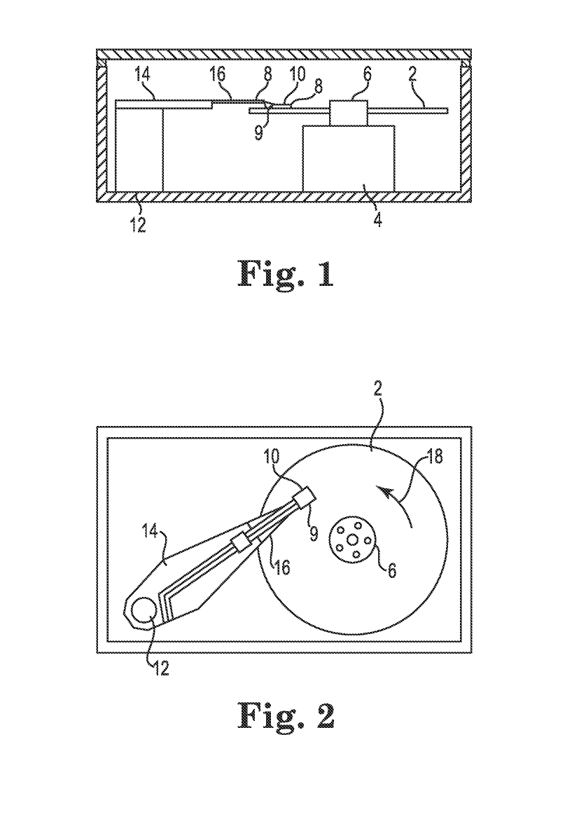

Referring now to the Figures, wherein the components are labeled with like numerals throughout the several Figures, and initially to FIGS. 1 and 2, an exemplary configuration of a magnetic recording disc drive is illustrated, which generally includes a magnetic recording disc 2 that is rotated by a hub 6 that is mechanically driven by drive motor 4. A slider with a read/write head or transducer 8 is located on the trailing end or surface 9 of a slider 10. A rigid arm 14 and a suspension element 16 connect the slider 10 to an actuator 12. The suspension element 16 provides a bias force that urges slider 10 toward the surface of disc 2. During operation of the disc drive, drive motor 4 rotates disc 2 at a constant speed in the direction of arrow 18. Actuator 12, which can be a linear or rotary motion coil motor, drives slider 10 generally radially across the plane of the surface of disc 2 so that read/write head 8 may access different data tracks on disc 2.

In order to meet the increasing demands for storing larger amounts of data on discs such as magnetic recording disc 2, lapping and polishing techniques can be used that enhance slider features. Typically, numerous sliders are fabricated from a single wafer having arrays of magnetic transducer heads deposited simultaneously on the wafer surface using semiconductor-type process methods. Then, rows of bars or slider bars are sliced from the wafer, each row bar being a row of units that are processed into sliders each having one or more magnetic transducers or heads on their end faces. Each row bar is bonded to a fixture or tool for further processing (e.g., lapping, cleaning, and/or formation of air-bearing surfaces) and then further diced or otherwise separated into individual sliders. In other processes, stacks or chunks are sliced from each wafer, wherein the stacks have multiple rows of units that are eventually processed into sliders. Each stack is bonded to a fixture or tool for lapping and eventual separation into individual sliders. In still other processes, individual sliders are lapped.

For many lapping processes, three steps are involved after double-sided lapping (DSL), although more or less than three steps may be used. However, a typical three-step process includes a rough lapping step, a fine lapping step, and a kiss lapping step. For a rough lapping step, the abrasive particles (e.g., diamonds) can be approximately 1 to about 5 micrometers in size, in some embodiments as large as 10 micrometers; for a fine lapping step, the abrasive particles can be approximately 0.1 to about 1 micrometer in size; and for a kiss lapping step, the abrasive particles can be less than 0.1 micrometer. To accomplish these steps, the row bar comprising multiple sliders is typically secured to a first carrier for the rough and fine lapping steps, and then removed from the first carrier and mounted on a second carrier for the kiss lapping step, although the slider bar may instead only be secured to one carrier throughout the lapping process or may instead be secured to a different carrier for each of the lapping steps (e.g., three carriers for three lapping steps). In any case, for each of the different steps of the lapping process, a front surface of the row bar is brought into contact with a lapping plate, then the lapping process is performed, and then the front surface and the lapping plate are moved out of contact with each other. This sequence of steps is repeated for each of the lapping steps, wherein a limitation of an embodiment of such a system is described below.

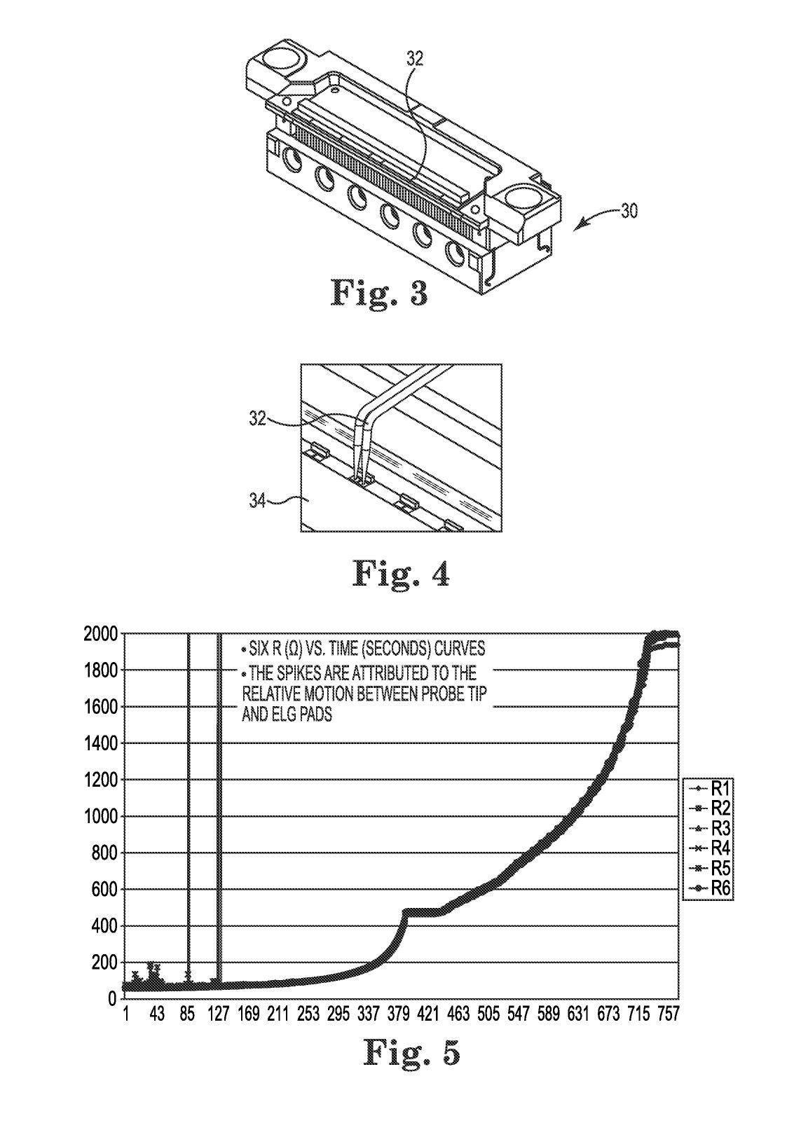

FIGS. 3 and 4 illustrate a 6-pair probe card connection 30 and an enlarged perspective view of a pair of probes 32 positioned relative to a pair of ELG pads 34, respectively. As shown in FIG. 4, the distal tips of the probes 32 are in contact with a top surface of the ELG pads 34. During the lapping process, this contact between the probe tips and ELG pads is used as electrical connection to provide measurements of the ELG resistance values, which in turn will determine when a desired amount of material is removed (i.e., which corresponds to achieving a desired stripe height from the air bearing surface). However, this contact can be broken or disrupted during touchdown, where a lapping plate and air bearing surface of a row bar come in contact with each other, as is illustrated in the graph of FIG. 5. This graph illustrates six ELG resistance vs. lapping time traces for a probe card connection of the type illustrated in FIG. 3, wherein the areas of discontinuity or spikes are attributed to the relative motion between the probe tips and ELG pads during the touchdown/lapping process.

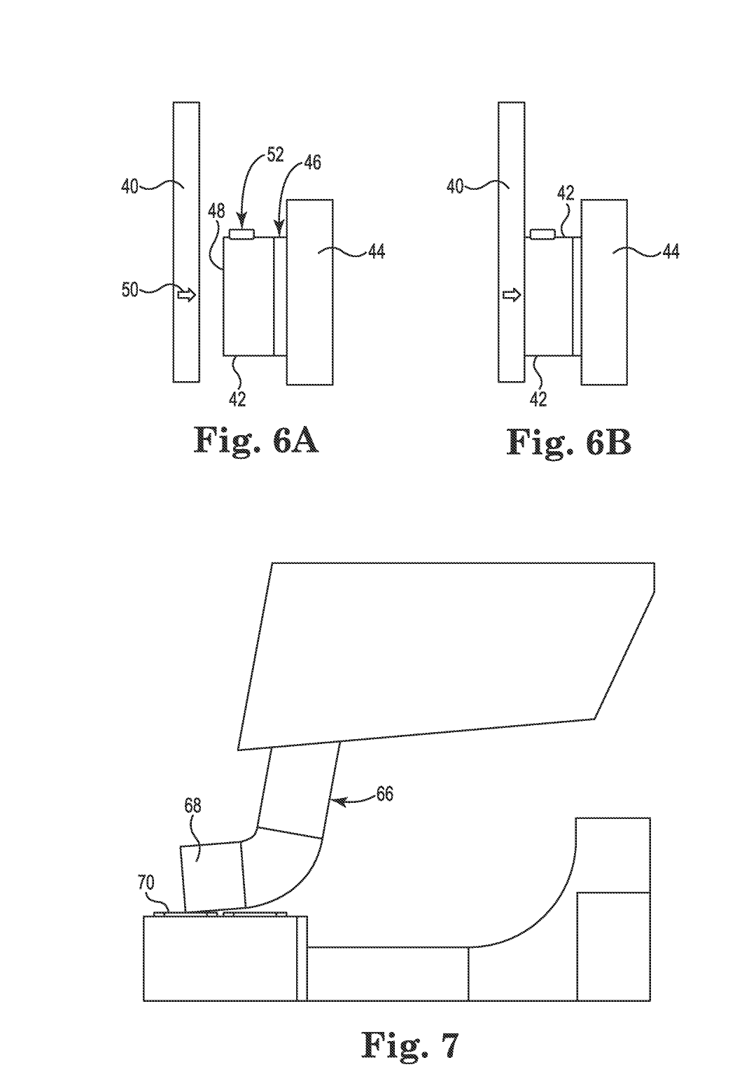

FIGS. 6a and 6b are side schematic views of an exemplary touchdown between a lapping plate 40 and an air bearing surface 48 of a row bar 42 that includes an ELG pad 52, wherein the row bar 42 is attached to a carrier 44 via a layer of adhesive 46. FIG. 6a illustrates the system in an open configuration prior to touchdown, wherein the lapping plate 40 moves in a direction 50 relative to the row bar 42. FIG. 6b illustrates the lapping plate 40 in contact with the air bearing surface of row bar 42. Because compression of the adhesive layer 46 during touchdown of the carrier 44 can induce displacement of the ELG pads 52 relative to probe tips with which they were in contact, the resulting displacement causes poor contact between the probe tip and ELG pad.

FIG. 7 illustrates an embodiment of a probe tip structure in accordance with the present invention, which provides for increased contact viability between probe tips and ELG pads, both during touchdown and during the lapping process. In general, a probe card is mounted or attached to a bridge carrier in a manner in which it can be removed and replaced, if desired. The probe card includes a body member or base member and pairs of extending probes 66. The extending probes 66 are configured so that when the probe card is positioned on the bridge carrier, distal tips 68 of the probes 66 extend below the bottom surface of the bridge carrier. These probes 66 are shaped such that they are preloaded with spring force in the direction of compression. That is, the shape of each of the probes 66 provides a force component along the compression-induced displacement direction of the probe 66. In this way, when the probe card is loaded onto the bridge carrier, the distal tips 68 of the probes 66 will be kept in contact with their respective ELG pads 70, as is illustrated in FIG. 7, for example. In particular, when the probe card is being loaded onto the bridge carrier, the probe card is movable in a direction of compression between a first position in which the distal end of at least one of the extending probes is spaced from a top surface a corresponding electronic lapping guide pad and a second position in which the distal end of the extending probe(s) contact the top surface the corresponding electronic lapping guide pad, wherein the extending probe(s) are pre-loaded with a predetermined spring force in the direction of compression. The direction of compression of a probe can be generally normal to the top surface of the corresponding electronic lapping guide when the probe card is in the second position.

In accordance with the invention, it is contemplated that all of the probes of a particular probe card can be preloaded with the same restoring force along the compression-induced displacement direction, or that some of the probes of a particular probe card can be preloaded with a different amount of force than other probes of the same probe card. In any case, each of the probes can be associated with a corresponding ELG pad with which it will be in contact when the probe card is loaded onto the bridge carrier.

In an embodiment of the present invention, the downward force provided by each of the preloaded distal tips 68 of probes 66 is within a few grams/tip. The amount of downward force is chosen to provide a sufficient force that maintains adequate electrical contact between the probe tips 68 and their respective ELG pads 70 during touchdown and the lapping processes but that does not cause excessive shearing force to deform or dislodge the row bar.

As shown best in FIG. 7, probe tip 66 is configured in such a way that it has a preferential moment of inertia in the compression direction. Further, the cantilever structure, as shown in FIG. 4, allows upward movement of the probe 66 associated with the compression. In this way, the probe 66 maintains electrical contact integrity in the sideways direction.

In accordance with the invention, the preloaded probes 66 may include a coating on their distal tips 68, wherein such a coating is selected to increase the friction between each of the tips 68 and its corresponding ELG pad 70. With such a coating, the downward force required to keep the tip 68 in contact with the ELG pad 70 can be greatly reduced. In an embodiment of the invention, the material selected for the top surface of the ELG pads and the material selected for the distal probe tips will result in a greatly enhanced coefficient of friction that will increase the “sticking force” with a minimal downward force to prevent shearing the row bar off the lapping carrier. These coating materials can be the same or different from each other. In a particular embodiment of the invention, the distal probe tips 68 are coated with gold to match the gold coating on top of the corresponding ELG pads 70, so that the static frictional coefficient approaches 1.2. However, it is understood that a number of different materials can be chosen, both for the coating on the probe tips and for the top surface of the ELG pads, wherein the combination of materials can be chosen to arrive at a desired coefficient of friction between the surfaces. That is, the coating material can be a material other than gold that provides the desired coefficient of friction between the surfaces. In any of the embodiments described herein, the distal end of at least one of the extending probes can include a first material, and the top surface of at least one of the electronic lapping guide pads can include a second material, wherein contact between the distal end of each extending probe and the top surface of the electronic lapping guide pad that it contacts provides a coefficient of friction greater than about 0.8. In other embodiments, the coefficient of friction will be less than about 0.8, but will still provide improved contact between the surfaces.

In accordance with an aspect of the present invention, it is further contemplated that the probe tip(s) are not preloaded as discussed above, but that at least one of the probe tip and the ELG pad surface is provided with a material or combination of materials that provides a desired coefficient of friction when the surfaces are in contact with each other, such as is described above relative to preloaded probes. In this way, contact between the surfaces can be improved as compared to surfaces that are not provided with any coatings.

The present invention has now been described with reference to several embodiments thereof. The foregoing detailed description and examples have been given for clarity of understanding only. No unnecessary limitations are to be understood therefrom. It will be apparent to those skilled in the art that many changes can be made in the embodiments described without departing from the scope of the invention. The implementations described above and other implementations are within the scope of the following claims.

What is claimed is:

1. A lapping system comprising:
a substrate comprising a front surface and at least one slider, wherein each slider comprises at least one electronic lapping guide pad; and
a probe card comprising at least one extending probe comprising a body member and a distal end, the probe card being movable in a direction of compression between a first position in which the distal end of a first extending probe is spaced from a top surface of one of a first electronic lapping guide pad and a second position in which the distal end of the first extending probe contacts the top surface the first electronic lapping guide pad, wherein the first extending probe is pre-loaded with a predetermined spring force in the direction of compression.

2. The lapping system of claim 1, wherein the probe carrier comprises a plurality of extending probes.

3. The lapping system of claim 2, wherein each of the plurality of extending probes is associated with one of the plurality of electronic lapping guide pads.

4. The lapping system of claim 1, wherein the probe card provides a minimum force of 1 gram for each probe in the direction of compression when the probe card is in the second position.

5. The lapping system of claim 1, wherein the direction of compression is normal to the top surface of the at least one electronic lapping guide when the probe card is in the second position.

6. The lapping system of claim 1, wherein the distal end of at least one of the extending probes comprises a first material and wherein the top surface of at least one of the electronic lapping guide pads comprises a second material, wherein contact between the distal end of each extending probe and the top surface of the electronic lapping guide pad that it contacts provides a coefficient of friction greater than about 0.8.

7. The lapping system of claim 6, wherein the distal end of the at least one extending probe comprises a gold coating layer.

8. The lapping system of claim 1, wherein the top surface of the at least one electronic lapping guide pads comprises a gold coating layer.

9. The lapping system of claim 1, wherein the distal end of at least one of the extending probes comprises a gold coating layer.

10. The lapping system of claim 1, wherein the top surface of at least one of the electronic lapping guide pads comprises a gold coating layer.

11. A lapping system comprising:
a substrate comprising a front surface and at least one slider, wherein each slider comprises at least one electronic lapping guide pad; and
a probe card comprising at least one extending probe comprising a body member and a distal end, the probe card being movable in a direction of compression between a first position in which the distal end of a first extending probe contacts a top surface of one of a first electronic lapping guide pad and a second position in which the distal end of the first extending probe is spaced from the top surface the first electronic lapping guide pad, wherein the distal end of the first extending probe comprises a gold coating layer.

12. A method of manufacturing a magnetic read-write head, comprising the steps of:
presenting a lapping system to a processing location relative to a lapping device, the lapping system comprising a substrate comprising a front surface and at least one slider, wherein each slider comprises at least one electronic lapping guide pad and a probe card comprising at least one extending probe comprising a body member and a distal end, the probe card being movable relative to the at least one slider in a direction of compression;
moving the probe card between a first position in which the distal end of a first extending probe is spaced from a top surface of a first of the at least one electronic lapping guide pads to a second position in which the distal end of the first extending probe contacts the top surface the first of the at least one electronic lapping guide pads, wherein the first extending probe is pre-loaded with a predetermined spring force in the direction of compression;
lapping the air bearing surface with the lapping device while measuring the electrical resistance of the first of the at least one electronic lapping guides with the first extending probe.

13. The method of claim 12, wherein each slider of the lapping system comprises a pair of electronic lapping guide pads.

14. The method of claim 12, wherein the distal end of the at least one extending probe comprises a gold coating layer.

15. The lapping system of claim 12, wherein the top surface of the at least one electronic lapping guide pads comprises a gold coating layer.
